(19) United States
(12) Patent Application Publication
(10) Pub. No.: US 2026/0363005 A1
(43) Pub. Date: Nov. 12, 2026

(54) SEMICONDUCTOR PACKAGE HAVING CONDUCTIVE BONDING LAYER AND METHOD OF MAKING THE SAME

(71) Applicant: ALPHA AND OMEGA SEMICONDUCTOR INTERNATIONAL LP, TORONTO (CA)

(72) Inventors: Bo Chen, Shanghai (CN); Chunya Wen, Santa Clara, CA (US); Zhen Huang, Shanghai (CN); Xuejun Wu, Shanghai (CN); Yulin Shen, Shanghai (CN)

(73) Assignee: ALPHA AND OMEGA SEMICONDUCTOR INTERNATIONAL LP, TORONTO (CA)

(21) Appl. No.: 19/203,347

(22) Filed: May 9, 2025

(51) Int. Cl. H10P 54/00; H10D 64/23; H10D 64/62; H10P 72/70; H10W 90/00; H10W 72/00; H10W 72/30; H10W 90/20

(52) U.S. Cl. CPC H10P 54/00; H10D 64/258; H10D 64/62; H10P 72/7402; H10W 90/00; H10P 72/7428; H10P 72/7436; H10P 72/744; H10W 72/07307; H10W 72/07332; H10W 72/07336; H10W 72/07341; H10W 72/334; H10W 72/352; H10W 90/20; H10W 90/732

(57) ABSTRACT

A semiconductor package comprises a first semiconductor chip, a second semiconductor chip, and a conductive bonding layer connecting the first semiconductor chip to the second semiconductor chip. A method, for fabricating a semiconductor package, comprising the steps of providing a wafer, applying a singulation process, selecting a first semiconductor chip, placing the first semiconductor chip onto a lead frame carrier, selecting a second semiconductor chip, applying a bonding process, and removing the lead frame carrier.

### FIELD OF THE INVENTION

The present invention relates generally to a semiconductor package and a method of making the same. More particularly, the present invention relates to the semiconductor package, having a conductive bonding layer and the method of making the same.

### BACKGROUND OF THE INVENTION

Protection Circuit Module (PCM) includes two MOSFET transistors connected in common drain to control current in battery charging and discharging process. Traditional PCM semiconductor package adopts a side-by-side structure as shown in FIG. 1. A semiconductor chip includes a back side common drain electrode D12, a first source electrode S1 and a first gate electrode G1 on a front side of the first transistor area, and a second source electrode S2 and a second gate electrode G2 on a front side of the second transistor area. In this traditional structure, current path is mostly a horizontal current flow between the first source electrode S1 and the second source electrode S2. Since the current needs to pass through an excessively long lateral path, resistance loss of the current during conduction process increases. Moreover, horizontal current conduction requires a larger plane space to accommodate the current path, which makes it difficult to further reduce the package size to meet the requirements of electronic equipment for miniaturization, lightweight and high-density integration.

With the continuous development of semiconductor technology, in recent years, a concept of vertical current flow PCM has been proposed. In contrast to the traditional horizontal current flow structure, vertical current flow PCM has potential advantages in improving semiconductor performance, optimizing circuit layout, etc. For example, U.S. Patent No. 6,194,290 to Kub et al. discloses a method for manufacturing semiconductor devices by low-temperature direct bonding wafers, manufacturing semiconductor devices with current conduction in the vertical direction from two semiconductor wafer substrates.

However, direct wafer bonding processes are usually high cost. Further, the existing semiconductor packaging uses stacked field effect transistors with a lead frame as a carrier. The stacked field effect transistors are packaged by first cutting the bonded wafers, then using the lead frame as a structural support for the chips, and providing circuit connections to complete the packaging. The process is complicated and the product size cannot be miniaturized due to the restriction of the lead frame.

### SUMMARY OF THE INVENTION

The present invention discloses a semiconductor package comprising a first semiconductor chip, a second semiconductor chip, and a conductive bonding layer connecting the first semiconductor chip to the second semiconductor chip.

A method for fabricating a semiconductor package is also disclosed. The method comprises the steps of providing a wafer, applying a singulation process, selecting a first semiconductor chip, placing the first semiconductor chip onto a lead frame carrier, selecting a second semiconductor chip, applying a bonding process, and removing the lead frame carrier.

### BRIEF DESCRIPTION OF THE DRAWINGS

FIG. 1 is a schematic diagram of a side-by-side structure of a conventional semiconductor package in the prior art.

FIG. 2 is a schematic diagram of a cross-section of a semiconductor package in examples of the present disclosure.

FIG. 3A is an X-ray image of a cross section of a stacking structure of a semiconductor package in examples of the present disclosure.

FIG. 3C is an optical image of an edge surface of a stacking structure of a semiconductor package in examples of the present disclosure.

FIG. 4 is a perspective view of a stacking structure of a semiconductor package in examples of the present disclosure.

FIG. 5 is a schematic diagram of the process flow of a semiconductor package preparation method in examples of the present disclosure.

FIG. 6 is a schematic diagram of the process flow of semiconductor chips preparation in examples of the present disclosure.

FIGS. 7A, 7B, 7C, 7D, 7E, 7F, 7G, 7H, 7I, 7J, 7K, 7L, 7M, and 7N are schematic diagrams of the structure of each process flow in the semiconductor package preparation method in examples of the present disclosure.

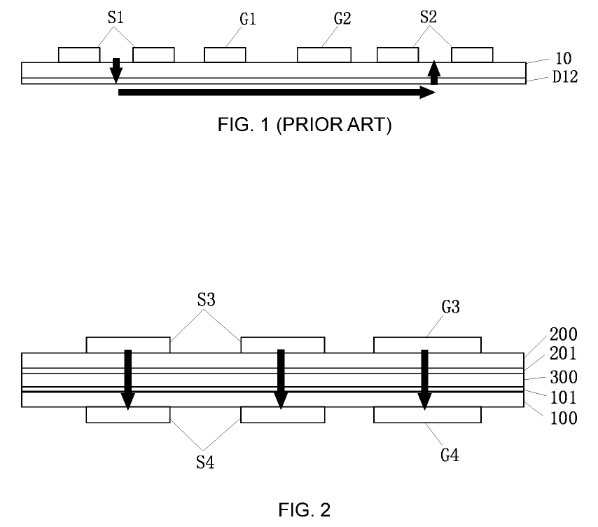

### DETAILED DESCRIPTION OF THE INVENTION

In examples of the present disclosure, the semiconductor package 1000 adopts chip scale package (CSP). The size of the CSP package is very close to the chip itself. In general, the ratio of the package area to the chip area is less than 1.2, and can even be close to 1, which is suitable for the trend of miniaturization and thinness of electronic equipment.

The semiconductor package 1000 adopts double-sided CSP, meaning, electrical electrodes for external contacts are provided on both top and bottom surfaces of the semiconductor package 1000.

In examples of the present disclosure, the stacking structure of the semiconductor package includes a first semiconductor chip 100, a second semiconductor chip 200, and a conductive bonding layer 300 located therebetween. The first semiconductor chip 100 and the second semiconductor chip 200 are electrically connected and attached via the conductive bonding layer 300 to form a vertically stacked semiconductor packaging structure.

In one example of the invention, the first semiconductor chip 100 and the second semiconductor chip 200 are cut from a same wafer.

Traditional semiconductor packaging uses a wafer-level bonding process, that is, first bonding wafer to wafer, and then cutting the bonded wafers into dice, which requires cutting through much thicker metal layer. The risk of damaging the circuit on the top of the chip increases. Moreover, a good die on a wafer matching a bad die on the other wafer produces a bad part, which greatly reduces the yield of the product.

In this invention, a semiconductor chip-level bonding process is used to replace the traditional wafer-level bonding process. That is, the semiconductor chips are first cut from the wafer and then bonded together. The cutting process is completed before the semiconductor chips are bonded. In examples of the present disclosure, the process cuts through much thinner wafer back metal, for example, only half of the metal thickness compare to the prior art cutting through the bonded wafers. The new process not only avoids the risk of circuit damage to the chips, but also removes bad dice on the wafer, and only selects good dies for back-to-back pairing and bonding, greatly improving the product yield.

The first semiconductor chip 100 and the second semiconductor chip 200 are bonded on the opposite sides of the conductive bonding layer 300, respectively, so as to realize the two semiconductor chips drain-to-drain stacking, and the two semiconductor chips share a conductive bonding layer. The conductive bonding layer provides a path for current conduction, realizing vertical current flow. The die-to-die bonding accuracy (attachment offset) follows the POD (Package Outline Drawing) tolerance.

The advantage of stacked chips over side-by-side chips in terms of source electrode resistance (Rss) depends on the silicon platform and substrate. The conductivity of the bonding material is much better than that of the wafer substrate. Due to the change in the current path, the on-state resistance is improved. In the traditional horizontal current conduction scheme, the current path is long. The vertical current conduction scheme enables the current to flow directly between the two semiconductor chips through the conductive bonding layer, greatly shortening the current path, reducing the on-resistance, and improving the performance and efficiency of the device.

Moreover, the vertical current conduction scheme reduces the package size by conducting the current in vertical direction, meeting the requirements of electronic devices for miniaturization, lightweight and high-density integration, especially for embedded applications such as smart phones, tablets, wearable devices, etc.

In addition, since the semiconductor package adopts a symmetrical structure, stress of the package is more uniformly distributed when subjected to external force or temperature changes, thereby reducing the degree of warping and achieving better warping performance.

In examples of the present disclosure, the conductive bonding layer 300 serves as a common drain of the first semiconductor chip 100 and the second semiconductor chip 200 by connecting the drain electrode of the first semiconductor chip 100 with the drain electrode of the second semiconductor chip 200.

In examples of the present disclosure, the first semiconductor chip 100 has a first drain region on one side facing the conductive bonding layer 300, and a first back metal layer 101 is formed on the first drain region. The first back metal layer 101 serves as the drain electrode of the first semiconductor chip 100, and the first semiconductor chip 100 is connected to the conductive bonding layer 300 through the first back metal layer 101.

The second semiconductor chip 200 has a second drain region on one side facing the conductive bonding layer 300, A second back metal layer 201 is formed on the second drain region. The second back metal layer 201 serves as the drain electrode of the second semiconductor chip 200, and the second semiconductor chip 200 is connected to the conductive bonding layer 300 through the second back metal layer 201.

The two semiconductor chips sandwich the conductive bonding layer 300 therebetween, which serves as the common drain region of the two semiconductor chips and also as the drain electrode of the semiconductor package.

In examples of the present disclosure, the first semiconductor chip 100 has a first source metal region and a first gate metal region on one side away from the conductive bonding layer 300, and the second semiconductor chip 200 has a second source metal region and a second gate metal region on one side away from the conductive bonding layer 300, wherein the first source metal region and the second source metal region at least partially overlap in vertical projection, and the first gate metal region and the second gate metal region at least partially overlap in vertical projection.

In examples of the present disclosure, the first source metal region and the second source metal region partially overlap in vertical projection. In examples of the present disclosure, the first source metal region and the second source metal region completely overlap in vertical projection.

In examples of the present disclosure, the first gate metal region and the second gate metal region partially overlap in vertical projection. In examples of the present disclosure, the first gate metal region and the second gate metal region completely overlap in vertical projection.

In the semiconductor package 1000 of this invention, since the source metal regions of the two semiconductor chips at least partially overlap in vertical projection, the current flows from the first source metal region of the first semiconductor chip 100 to the second source metal region of the second semiconductor chip 200 through the conductive bonding layer 300, and the current can flow in the vertical direction, which shortens the current path compared to the horizontal current conduction scheme, thereby improving the on-state resistance.

In examples of the present disclosure, a passivation layer may be disposed overlaying the source metal and the gate metal with opening windows to expose parts of the source metal and the gate metal. A solderable layer is formed on the gate and source window areas of the first semiconductor chip 100 and the second semiconductor chip 200. The solderable layer is used for connection in the surface mount technology (SMT) process.

The solderable layer includes a first source solderable layer formed on the first source metal region, and a first gate solderable layer formed on the first gate metal region, the first source solderable layer serves as the source electrode S3 of the first semiconductor chip 100, and the first gate solderable layer serves as the gate electrode G3 of the first semiconductor chip 100.

The solderable layer also includes a second source solderable layer formed on the second source metal region, and a second gate solderable layer formed on the second gate metal region, the second source solderable layer serves as the source electrode S4 of the second semiconductor chip 200, and the second gate solderable layer serves as the gate electrode G4 of the second semiconductor chip 200.

In examples of the present disclosure, the source electrode S3 of the first semiconductor chip 100 and the source electrode S4 of the second semiconductor chip 200 partially overlap in vertical projection. In examples of the present disclosure, the source electrode S3 of the first semiconductor chip 100 and the source electrode S4 of the second semiconductor chip 200 completely overlap in vertical projection.

In examples of the present disclosure, the gate electrode G3 of the first semiconductor chip 100 and the gate electrode G4 of the second semiconductor chip 200 partially overlap in vertical projection. In examples of the present disclosure, the gate electrode G3 of the first semiconductor chip 100 and the gate electrode G4 of the second semiconductor chip 200 completely overlap in vertical projection.

When the current is conducted from the first semiconductor chip 100 to the second semiconductor chip 200, as shown in FIG. 2, the current flows from the source electrode S3 of the first semiconductor chip 100 to the source electrode S4 of the second semiconductor chip 200 through the conductive bonding layer 300.

In examples of the present disclosure, when the current is conducted from the second semiconductor chip 200 to the first semiconductor chip 100, the current flows from the source electrode S4 of the second semiconductor chip 200 to the source electrode S3 of the first semiconductor chip 100 through the conductive bonding layer 300.

In examples of the present disclosure, the conductive bonding layer 300 includes any one bonding material or a combination of multiple bonding materials in a solder preform, solder foil, solder paste, or lead-free soldering material. In examples of the present disclosure, the conductive bonding layer 300 comprises a Ti layer overlaying a cupper layer formed as back metal layer of the first semiconductor chip 100 and the second semiconductor chip 200 respectively.

In examples of the present disclosure, the conductive bonding layer 300 is used as a semiconductor chip attachment material. In examples of the present disclosure, a solder preform can be used. A solder preform is a molded part prefabricated using a solderable material.

For example, a solder preform can be a molded part made of an ordinary solderable material. Furthermore, a high-temperature solderable material can also be used, which can maintain good solderable performance in a high-temperature environment and is suitable for application scenarios that need to withstand a high-temperature working environment. Furthermore, lead-free soldering materials, such as high-temperature lead-free solder paste (Durafuse HT), can also be used to make lead-free solder preforms, which are suitable for application scenarios with high requirements for safety and stability.

The shape and size of the solder preform match the semiconductor chip and can adapt to specific semiconductor chip connection requirements.

During the packaging process, the solder preform is attached to the first semiconductor chip 100 using adhesive material; then, the second semiconductor chip 200 is attached to the solder preform using adhesive material; and then high-temperature reflow is performed in a vacuum environment to connect the two semiconductor chips. After the final test (FT), a semiconductor package of chip-scale packaging is obtained. During the reflow process, the adhesive materials evaporate, and no residue remains after reflow.

In examples of the present disclosure, the conductive bonding layer 300 can also be a solder foil. Solder foil is a thin sheet of solderable material, usually made of a low-melting point metal alloy (such as tin-based, lead-based or lead-free alloy), with a thickness between a few microns and tens of microns. It fills the gap of the solder joint after heating and melting to achieve electrical connection and mechanical fixation.

Solder paste is also an option. Solder paste is a homogeneous paste made of alloy solder powder, paste flux and additives, which has viscosity and thixotropy. At room temperature, solder paste can be used to temporarily fix a chip at a specified position; when heated to a certain temperature, the flux volatilizes and the alloy powder melts to form a permanent electrical and mechanical connection.

In practical applications, one material can be selected or multiple materials can be combined based on the specific semiconductor chip structure, connection requirements, working environment and other factors. For example, if both the advantages of solder preform and the filling properties of solder paste are required, the two can be used in combination, first placing the solder preform, and then using solder paste to fill the gap around the solder preform to ensure the connection reliability and conductivity of the conductive bonding layer.

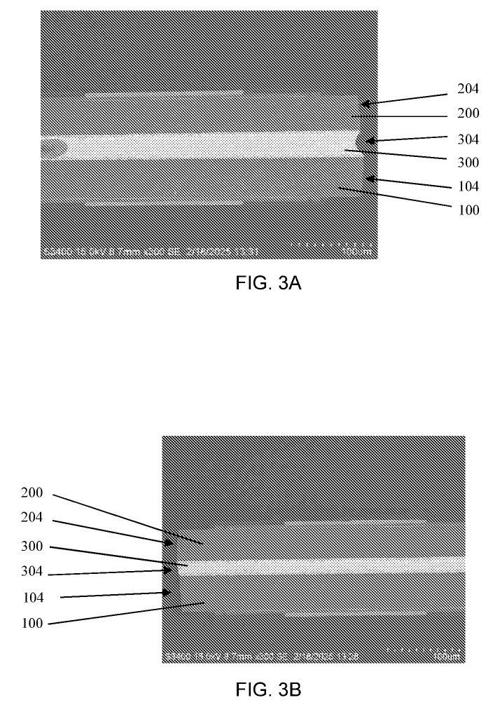

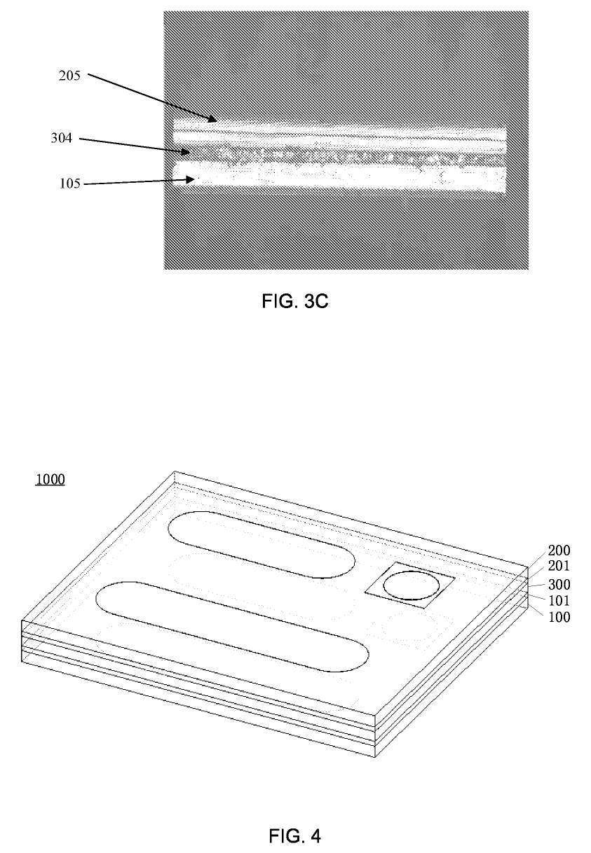

In examples of the present disclosure, as shown in FIG. 3A, in one side wall of the semiconductor package 1000 of this example, the conductive bonding layer 300 is recessed from edges of the first semiconductor chip 100 and the second semiconductor chip 200. In examples of the present disclosure, a side wall 304 of the conductive bonding layer 300 is recessed from a corresponding side wall 104 of the first semiconductor chip 100 and/or a corresponding side wall 204 of the second semiconductor chip 200. The side wall 304 of the conductive bonding layer 300, the corresponding side wall 104 of the first semiconductor chip 100 and the corresponding side wall 204 of the second semiconductor chip 200 are not coplanar; or

As shown in FIG. 3B, the conductive bonding layer 300 protrudes from the first semiconductor chip and/or the second semiconductor chip. In examples of the present disclosure, the side wall 304 of the conductive bonding layer 300 protrudes from the corresponding side wall 104 of the first semiconductor chip 100 and/or the corresponding side wall 204 of the second semiconductor chip 200. The side wall 304 of the conductive bonding layer 300, the corresponding side wall 104 of the first semiconductor chip 100 and the corresponding side wall 204 of the second semiconductor chip 200 are not coplanar; or

As shown in FIG. 3C, the conductive bonding layer 300 seeps out of the edge of the first semiconductor chip and/or the second semiconductor chip. In examples of the present disclosure, the side wall 304 of the conductive bonding layer 300 extends to cover a portion of the corresponding side wall 104 of the first semiconductor chip 100 and/or a portion of the corresponding side wall 204 of the second semiconductor chip 200, and the boundary of the side wall 304 of the conductive bonding layer 300 is irregularly shaped. The side wall 304 of the conductive bonding layer 300, the corresponding side wall 104 of the first semiconductor chip 100 and the corresponding side wall 204 of the second semiconductor chip 200 are not coplanar.

In examples of the present disclosure, the size of the conductive bonding layer 300 can be convex or concave to the size of the first semiconductor chip 100 and the second semiconductor chip 200, and the device total size is within the POD definition range. The protrusion or depression of the conductive bonding layer provides mold locking effect to the encapsulation after the product SMT. On the contrary, a smooth interface is not good for the encapsulation to lock.

In examples of the present disclosure, as shown in FIG. 3C, traces of cutting marks 105 on the side wall 104 of the first semiconductor chip 100 are not continuous with traces of cutting marks 205 on the corresponding side wall 204 of the second semiconductor chip 200.

In examples of the present disclosure, the difference of the traces of cutting marks at the side walls of the first semiconductor chip 100 and the second semiconductor chip 200 indicates the first semiconductor chip 100 and the second semiconductor chip 200 are first singulated by wafer cutting before stacked bonded together by a bonding process.

Based on the wafer cutting machine capability, it is necessary to maintain the precision in wafer cutting process such that the wafer cutting offsets between the first semiconductor chip 100 and the second semiconductor chip 200 remain within the POD definition range. Based on the different cutting offset values generated by the corresponding side walls 104 of the first semiconductor chip 100 and the corresponding side walls 204 of the second semiconductor chip 200 in different cutting processes and the alignment error in the bonding process, the corresponding side walls 104 of the first semiconductor chip 100 and the corresponding side walls 204 of the second semiconductor chip 200 are non-coplanar.

The side wall 304 of the conductive bonding layer 300 is formed without cutting during the bonding process of the first semiconductor chip 100 and the second semiconductor chip 200. Therefore, no trace of cutting marks left on the side walls 304. Due to the fact that the side wall 304 of the conductive bonding layer 300, the corresponding side wall 104 of the first semiconductor chip 100 and the corresponding side wall 204 of the second semiconductor chip 200 are formed in different steps and the allowable tolerance associated with each step, the side wall 304 of the conductive bonding layer 300, the corresponding side wall 104 of the first semiconductor chip 100 and the corresponding side wall 204 of the second semiconductor chip 200 are not coplanar. Dimension deviation of each element is within the POD definition range.

The side wall 304 of the conductive bonding layer 300, the corresponding side wall 104 of the first semiconductor chip 100 and the corresponding side wall 204 of the second semiconductor chip 200 together define a side wall of the semiconductor package 1000. Different from the prior art process where a semiconductor CSP device cut from a bonded wafer exhibits a smooth side wall substantially in one plane on each side of the device, a side wall of the CSP semiconductor package 1000 of this invention comprises segments of side walls that are not coplanar.

In examples of the present disclosure, the first semiconductor chip 100 and the second semiconductor chip 200 are singulated from a same semiconductor wafer so they comprise the same semiconductor substrate.

In examples of the present disclosure, the first semiconductor chip 100 and the second semiconductor chip 200 are both manufactured on a same semiconductor wafer substrate. In examples of the present disclosure, the semiconductor wafer substrate can be an N-type substrate or a P-type substrate. It should be understood that the N-type and P-type here only represent the conductivity type, and the doping concentration can be selected as needed.

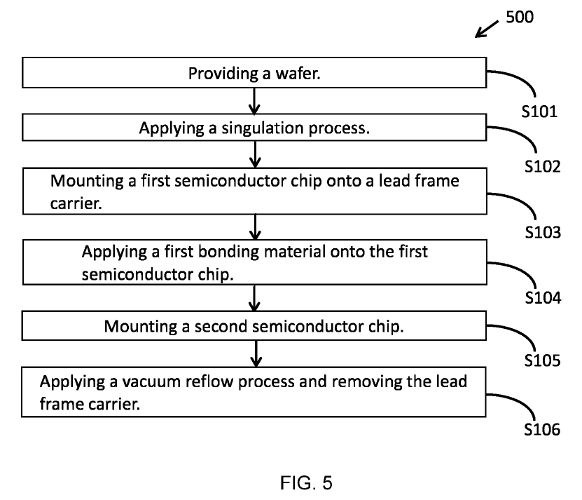

On the other hand, a method 500 for preparing a semiconductor package as described above is also provided, as shown in FIG. 5. The method 500 comprises the following steps:

S101, providing a wafer 10 comprising a plurality of semiconductor chips form thereon.

S102, dicing the wafer 10 to singulate the plurality of semiconductor chips from the wafer 10.

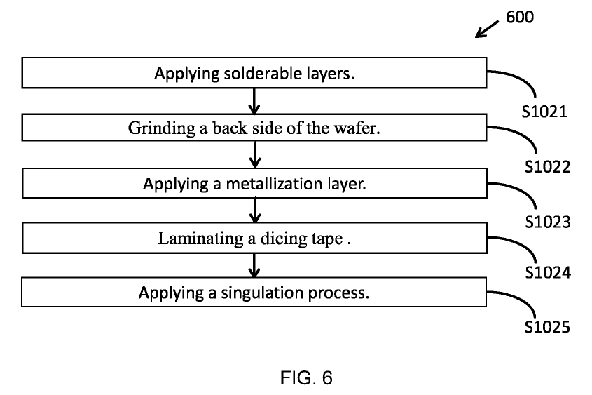

The step S102 of dicing the wafer 10 further comprises (FIG. 6 shows the process 600):

S1021, applying a solderable layer to the gate metal and the source metal of the wafer 10 respectively.

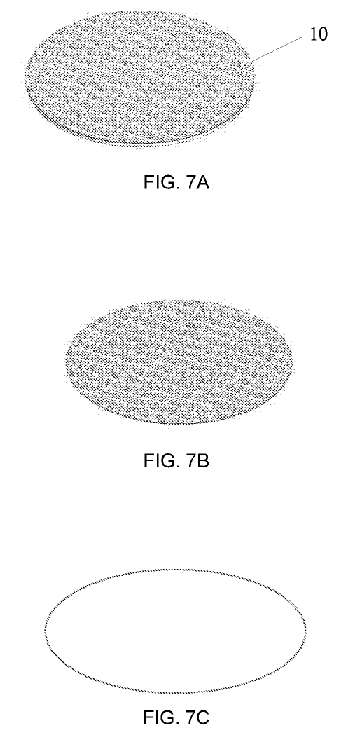

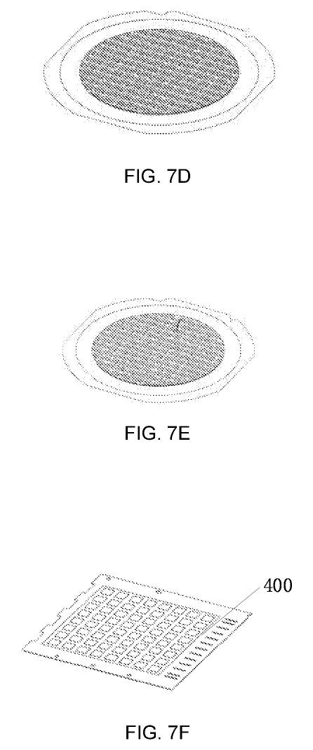

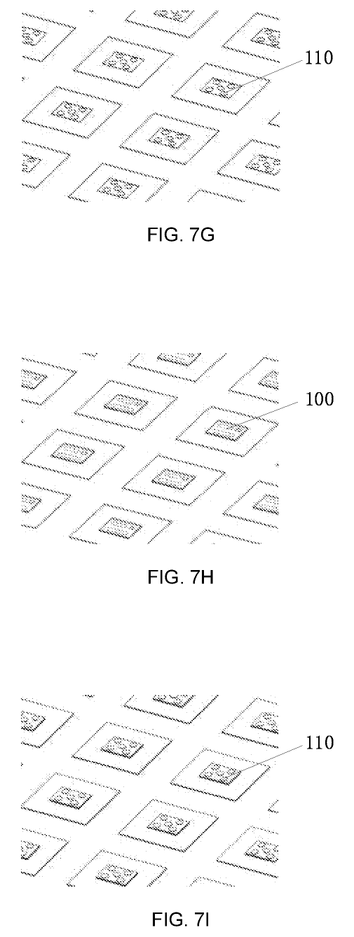

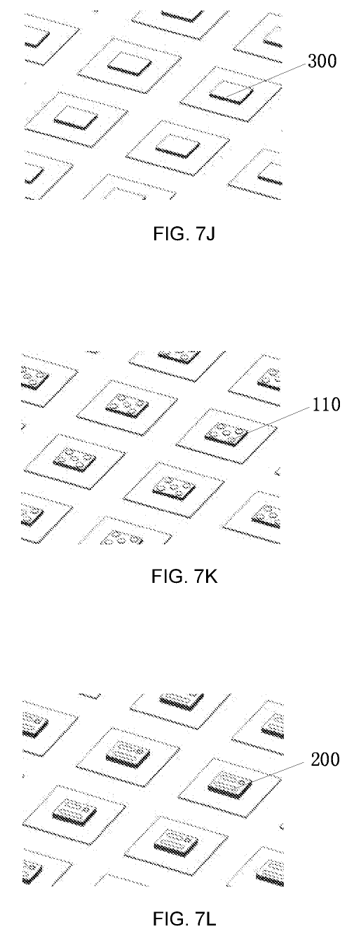

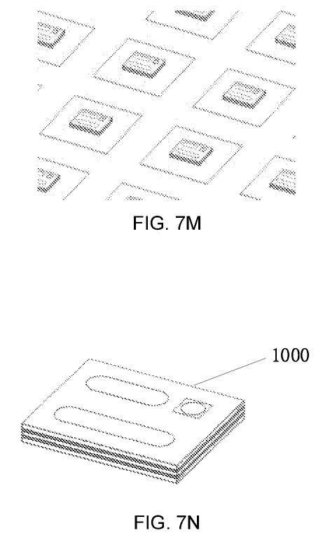

First, prepare a wafer, as shown in FIG. 7A. The solderable layer is applied to the opening windows of a passivation layer exposing the gate metal and the source metal on the top surface of the wafer, as gate electrodes and source electrodes. The solderable layer can be applied in one layer or more layers.

S1022, backside grinding the wafer.

As shown in FIG. 7B, the schematic diagram of the backside grinding of the wafer is shown, and the wafer is back ground to reduce the wafer thickness to a target value.

S1023, applying a metal layer to the back surface of the wafer after backside grinding.

As shown in FIG. 7C, a schematic diagram of wafer backside metallization is shown, and a metal layer is applied to the backside of the wafer to metallize the back surface of the wafer. In one example of the invention, the backside metallization layer comprises Ti/Ni/Au. In another example of the invention, the backside metallization layer comprises Ti/Cu/Ti.

S1024, laminating a dicing tape to the back of the wafer.

As shown in FIG. 7D, a schematic diagram of wafer lamination is shown, and the dicing tape is laminated to the back of the wafer for wafer dicing.

S1025, dicing the wafer to form a plurality of singulated semiconductor chips to obtain the above-mentioned first semiconductor chip 100 and second semiconductor chip 200.

As shown in FIG. 7E, a schematic diagram of wafer dicing is shown, and blade dicing is performed at the wafer scribe line to separate the wafer into a plurality of independent, CSP-level semiconductor chips.

S103, attaching the first semiconductor chip 100 to a lead frame carrier by adhesive.

First, prepare a lead frame carrier, as shown in FIG. 7F, a schematic diagram of the prepared lead frame carrier. As shown in FIG. 7G, an enlarged diagram of a first application of adhesive 110is shown, and the adhesive 110 is selectively disposed on the lead frame carrier.

As shown in FIG. 7H, an enlarged diagram of bottom semiconductor chips attachment is shown, the bottom chips are picked up from the dicing tape, and flipped attached with each front surface attached to lead frame carrier by the adhesive 110. S104, disposing a conductive bonding material layer 130 over the back surface of the first semiconductor chip 100 away from the lead frame carrier.

Taking an example for using solder preforms as the conductive bonding material layer 130, as shown in FIG. 7I, an enlarged diagram of a second application of adhesive 110 is shown. The adhesive 110 is applied onto the back surface of the first semiconductor chip 100.

As shown in FIG. 7J, an enlarged diagram of the solder preform attachment is shown.A solder preform is attached to the back side of each flipped first semiconductor chip 100 by the adhesive 110 disposed on the back surface of the first semiconductor chip 100.

S105, attaching the back of the second semiconductor chip 200 to the side of the conductive bonding material layer 130 away from the first semiconductor chip 100. The second semiconductor chip 200 is aligned with the first semiconductor chip 100.

As shown in FIG. 7K, an enlarged view of a third application of the adhesive 110, the adhesive 110 is applied onto the solder preforms.

As shown in FIG. 7L, an enlarged view of the top semiconductor chip attachment, the second semiconductor chip 200 is taken directly from the cutting tape. The back surface of each of the second semiconductor chip 200 is attached to a corresponding solder preform by the adhesive 110 disposed on the corresponding solder preform.

S106, performing vacuum reflow, and removing the lead frame carrier to prepare a semiconductor package.

As shown in FIG. 7M, an enlarged view of the package during vacuum reflow is shown. Vacuum reflow is carried out in a formic acid environment.

As shown in FIG. 7N, the structural schematic diagram of the chip scale package is shown. The lead frame carrier is removed after reflow to obtain a double-sided chip scale semiconductor package.

In examples of the present disclosure, during the vacuum reflow process, the adhesive 110 is removed by evaporation.

In examples of the present disclosure, before reflow, the semiconductor chips and the conductive bonding material are temporarily fixed on the lead frame (LDF) using adhesive. The adhesive evaporates during the reflow process, and no residue remains after reflow.

In examples of the present disclosure, taking example for using solder paste as the conductive bonding layer 300, a high-temperature adhesive material, such as solder paste, is applied to the flipped back side surface of the first semiconductor chip 100; and back surface of the second semiconductor chip 200 is attached to the high-temperature adhesive material, followed by a high-temperature reflow to connect the top second semiconductor chip 200 to the bottom first semiconductor chip 100.

During reflow process of the solder preforms and the solder paste, there is almost no offset shifting between the first semiconductor chip 100 and the second semiconductor chip 200 due to the self-alignment mechanism of liquid solder. The bonding alignment accuracy of the first semiconductor chip 100 and the second semiconductor chip 200 is based on the machine capability, and the bonding offset value is maintained within the POD definition range.

It can be seen from the package cross sections and X-ray observations in FIGS. 3A and 3B that the conductive bonding layer 300 provides a stable bonding line thickness inside the space between the first semiconductor chip 100 and the second semiconductor chip 200 and the double-sided chip scale semiconductor package has no warping after high-temperature solder reflow.

In another example of the invention, the step S104 may be skipped and the second semiconductor chip 200 directly stacks on the first semiconductor chip 100 with the second back metal layer 201 of the second semiconductor chip 200 interfacing first back metal layer 101 of the first semiconductor chip 100. In case the backside metals comprise Ti/Cu/Ti, strong bonding may be created after the stacking assembly subjects to high pressure above 1.9 MPa and high temperature of 400 degree C. In such case, at least a portion of the semiconductor chip backside metal serves as the conductive bonding layer 300.

The advantages or beneficial effects of the above technical solution are: the present invention realizes vertical current flow and reduces the on-state resistance by stacking two semiconductor chips with drain to drain connection. The two semiconductor chips sandwich a conductive bonding layer therebetween. In process, the semiconductor chip level bonding process is used to replace the traditional wafer level bonding, the wafer cutting process is completed before bonding process, which reduces the cutting complexity, avoids the risk of damage to the chip circuit by cutting stress, and improves the processability and productivity. In addition, the semiconductor package adopts a symmetrical structure, which enhances the device's anti-warping ability and reduces the package size.

Those of ordinary skill in the art may recognize that modifications of the embodiments disclosed herein are possible. For example, a thickness of the conductive bonding layer may vary. Other modifications may occur to those of ordinary skill in this art, and all such modifications are deemed to fall within the purview of the present invention, as defined by the claims.

1. A semiconductor package comprising:
a first semiconductor chip being flipped, the first semiconductor chip comprising:
a back surface;
a front surface; and
a side wall;
a conductive bonding layer comprising:
a front surface;
a back surface; and
a side wall; and
a second semiconductor chip comprising:
a front surface;
a back surface; and
a side wall;
wherein the back surface of the first semiconductor chip is directly attached to the back surface of the conductive bonding layer;
wherein the front surface of the conductive bonding layer is directly attached to the back surface of the second semiconductor chip;
wherein the side wall of the first semiconductor chip, the side wall of the conductive bonding layer and the side wall of the conductive bonding layer together define a side wall of the semiconductor package; and
wherein the side wall of the first semiconductor chip, the side wall of the conductive bonding layer, and the side wall of the second semiconductor chip are not coplanar.

2. The semiconductor package of claim 1, wherein the conductive bonding layer serves as a common drain of the first semiconductor chip and the second semiconductor chip; and
wherein the conductive bonding layer connects a drain electrode of the first semiconductor chip to a drain electrode of the second semiconductor chip.

3. The semiconductor package of claim 1, wherein a front side of the first semiconductor chip away from the conductive bonding layer comprises a first source metal and a first gate metal;
wherein a front side of the second semiconductor chip away from the conductive bonding layer comprises a second source metal and a second gate metal; and
wherein the first source metal and the second source metal at least partially overlap in a vertical projection.

4. The semiconductor package of claim 3 further comprising:
a first source solderable layer formed on the first source metal;
a first gate solderable layer formed on the first gate metal;
a second source solderable layer formed on the second source metal; and
a second gate solderable layer formed on the second gate metal.

5. The semiconductor package of claim 1, wherein the conductive bonding layer comprises a solder preform, a solder foil, a solder pastes, or a lead-free soldering material.

6. The semiconductor package of claim 1, wherein the conductive bonding layer protrudes or recesses from the first semiconductor chip or the second semiconductor chip.

7. The semiconductor package of claim 1, wherein traces of cutting marks on the side wall of the first semiconductor chip are discontinuous from traces of cutting marks on the second semiconductor chip.

8. The semiconductor package of claim 1, wherein the first semiconductor chip and the second semiconductor chip are formed from a same semiconductor wafer substrate.

9. The semiconductor package of claim 1, wherein the side wall of the conductive bonding layer excludes cutting marks.

10. The semiconductor package of claim 1, wherein the conductive bonding layer seeps out of an edge of the first semiconductor chip or the second semiconductor chip.

11. A method for fabricating a semiconductor package, the method comprising the steps of:
providing a wafer comprising
a plurality of semiconductor chips;
applying a singulation process separating the plurality of semiconductor chips, each semiconductor chip of the plurality of semiconductor chips comprising:
a front surface,
a back surface opposite the front surface,
a first electrode on the front surface,
a second electrode on the front surface, and
a third electrode on the back surface;
selecting a first semiconductor chip from the plurality of semiconductor chips;
placing the first semiconductor chip onto a lead frame carrier with the front surface of the first semiconductor chip facing the lead frame carrier;
selecting a second semiconductor chip from the plurality of semiconductor chips, and stacking the second semiconductor chip onto the first semiconductor chip;
applying a bonding process so that a conductive bonding layer connects the back surface of the second semiconductor chip to the back surface of the first semiconductor chip; and
removing the lead frame carrier so as to form the semiconductor package.

12. The method of claim 11, before the step of applying the singulation process, further comprising the steps of:
applying a solderable layer to the first electrode and the second electrode of each of the plurality of semiconductor chips on a front side of the wafer;
grinding a back side opposite the front side of the wafer;
applying a metallization layer to the ground back side of the wafer; and
laminating a dicing tape to a back side of the wafer with the metallization layer.

13. The method of claim 12, wherein the step of applying the metallization layer comprises forming Ti/Cu/Ti metallization on the back surface of each of the plurality of the semiconductor chips.

14. The method of claim 13, wherein the step of applying the bonding process comprises applying a high pressure and high temperature process to bond an exposed Ti on the back surface of the first semiconductor chip to an exposed Ti on the back surface of the second semiconductor chip.

15. The method of claim 12, after the step of applying the bonding process, further comprising the step of:
applying a vacuum reflow process.

16. The method of claim 15, wherein the step of placing the first semiconductor chip onto the lead frame carrier comprises using adhesive; and the adhesive is removed by evaporation during the step of applying the vacuum reflow process.

17. The method of claim 15, wherein the first semiconductor chip is attached to the lead frame carrier by a first adhesive, the conductive bonding layer is attached to the first semiconductor chip by a second adhesive, the second semiconductor chip is attached to the conductive bonding layer a third adhesive, and during the step of applying the vacuum reflow process, the first adhesive, the second adhesive, and the third adhesive are removed by evaporation.

18. The method of claim 15, wherein, during the step of applying the vacuum reflow process, the second semiconductor chip is self-aligned with the first semiconductor chip.

19. The method of claim 11, wherein the first semiconductor chip is flipped;
wherein the first semiconductor chip further comprises:
a side wall;
wherein the conductive bonding layer further comprises:
a side wall;
wherein the first semiconductor chip further comprises:
a side wall;
wherein the back surface of the first semiconductor chip is directly attached to the back surface of the conductive bonding layer;
wherein the front surface of the conductive bonding layer is directly attached to the back surface of the second semiconductor chip;
wherein the side wall of the conductive bonding layer directly connects the side wall of the first semiconductor chip to the side wall of the second semiconductor chip;
wherein the side wall of the first semiconductor chip and the side wall of the conductive bonding layer are not coplanar;
wherein the side wall of the conductive bonding layer and the side wall of the second semiconductor chip are not coplanar; and
wherein the side wall of the first semiconductor chip and the side wall of the second semiconductor chip are not coplanar.

20. The method of claim 11, wherein the semiconductor package is a dual-side chip scale semiconductor package.
